(19) United States
(12) Patent Application Publication
(10) Pub. No.: US 2008/0170379 A1
(43) Pub. Date: Jul. 17, 2008

(54) Optical Receiver Having Improved Shielding

(76) Inventors: Suresh Basoor, Singapore (SG); Wai Ming Beh, Singapore (SG); Wee Sin Tan, Singapore (SG); Park Hong Yee, Singapore (SG)

Correspondence Address: Kathy Manke;Avago Technologies Limited, 4380 Ziegler Road, Fort Collins, CO, 80525, US

(21) Appl. No.: 11/622,870

(22) Filed: Jan. 12, 2007

(51) Int. Cl. H05K 9/00

(52) U.S. Cl. 361/818

(57) ABSTRACT

An apparatus having a die, a carrier, and a plurality of shielding wires. The die has a top surface through which EMI is received. The carrier has a first surface on which the die is mounted by attaching the die to the first surface using a surface of the die other than the top surface. The carrier also includes a plurality of electrical traces, the die being connected to two of the traces. The shielding wires cross the top surface of the die and are connected to a shielding trace in the carrier. The shielding trace is held at a constant potential. The shielding wires are positioned such that the EMI received by the die is reduced below the level that would be received without the shielding wires. The die could include a light detector.

### BACKGROUND OF THE INVENTION

Optical transceivers are utilized in a number of systems to transmit and receive data and to implement proximity detectors. Such devices typically include a light source, which is typically a light emitting diode (LED) that is used to transmit data by modulating the intensity of the light source and a photodiode that receives the modulated light signals. Optical transceivers operating in the infrared are utilized in computers and handheld devices for transferring data from one device to another without requiring that the devices be connected together by a wire or cable. In such systems, the two devices are positioned relative to one another such that light from the transmitter in the first device is received by the optical receiver in the second device, and vice versa.

In a proximity detector, the light from the transmitter in the transceiver is received by the receiver in the transceiver after the light has been reflected from the surface of an object that is being detected. The amount of light that is received by the receiver is a function of the surface properties of the object and the distance between the object and the transceiver. Such proximity detectors are utilized in handheld devices such as cellular telephones to adjust the amplifier levels in response to the user placing the device close to the user's face.

In both applications, the light levels received by the photodiode in the receiver can be quite small. In the case of a data communications link, there is a tradeoff between the amount of light received and the degree of precision required in aligning the two communicating devices. If the light source is designed to provide a very narrow beam of light, the photodiode in the receiver will receive a large signal when the devices are correctly aligned, since most of the light will be received by the photodiode. However, small errors in alignment result in the light beam from the transmitter in the first device missing the receiver in the second device. In practice, the required levels of alignment are not achievable by utilizing manual alignment techniques in the field.

To provide increased alignment tolerance, the transceiver beam profile is often set to be much wider than the size of the photodiode. While such an arrangement provides improved tolerance to mis-alignment, the photodiode only receives a small fraction of the light that is transmitted. Hence, noise and interference problems are encountered at the receiver.

Similarly, the receiver in a proximity detector also receives only a small fraction of the light transmitted by the transmitter. In this case, even if the transmitter forms a relatively narrow light beam, the beam profile is spread by the reflecting surface which is typically a surface having a low reflectivity that introduces a significant degree of scattering into the optical path. Hence, the receiver sees a beam having a cross-section that is much larger than the photodiode, and hence, the signal-to-noise ratio in the receiver is also small.

In principle, the collection angle of the receiver can be increased by providing an optical element that collects light over an area that is much larger than the photodiode and then focuses that light on the photodiode. However, in many applications, there is a limit to the size of the transceiver. Many handheld devices such as cellular telephones fall into this category. Hence, some other mechanism for accommodating the low signal levels at the receiver are needed.

One source of noise at the receiver is electrical magnetic interference (EMI) from various electrical devices that are operating in the vicinity of the optical transceiver. To accommodate the low signal levels, the receivers require high gain amplifiers that are subject to noise from the various EMI sources. In principle, this noise could be removed by shielding the receiver. Various prior art devices utilize EMI shields to reduce the EMI interference; however, these shields present other problems.

First, the shields increase the size of the transceiver. The shield is essentially a metal enclosure that surrounds the transceiver on the sides of the transceiver that are not connected to the substrate on which the transceiver is mounted or needed to transmit and receive light. In transceivers designed for use in handheld devices, the transceivers are quite small, and hence, the shield represents a significant portion of the final transceiver size. As noted above, size is particularly important for devices that are to be incorporated in cellular telephones and similar handheld devices.

Second, the shield increases the cost of the transceiver and of the fabrication of the final handheld device. The shield is typically placed over the transceiver and soldered to the substrate on which the transceiver is mounted and connected to ground. This represents a significant increase in the assembly labor. Further, this labor is incurred by the manufacturer of the handheld device, and hence, does not benefit from the same level of economies of scale inherent in the manufacture of the transceivers. In addition, the shield itself represents a significant fraction of the cost of the final transceiver. Finally, this external shield must be attached such that it is aligned with the molded package in a manner that assures that the shield and package are aligned to the same plane so that the transceiver can be properly aligned and soldered to a printed circuit board in the product that utilizes the transceiver.

### SUMMARY OF THE INVENTION

The present invention includes an apparatus having a die, a carrier, and a plurality of shielding wires. The die has a top surface through which EMI is received. The carrier has a first surface on which the die is mounted by attaching the die to the first surface using a surface of the die other than the top surface. The carrier also includes a plurality of electrical traces, the die being connected to two of the traces. The shielding wires cross the top surface of the die and are connected to a shielding trace in the carrier. The shielding trace is held at a constant potential. The shielding wires are positioned such that the EMI received by the die is reduced below the level that would be received without the shielding wires. In one aspect of the invention, the die is a light receiving die having a light detector thereon that receives light through an aperture on a top surface of the light receiving die, and the aperture underlies the shielding wires. In another aspect of the invention, a layer of clear material covers the light receiving die and the shielding wires, the light receiving die being encapsulated by the layer of clear material and the carrier. In another aspect of the invention, the apparatus also includes a light transmitting die bonded to the carrier and covered by the layer of clear material. In yet another aspect of the invention, the light receiving die is characterized by a height, and the first surface of the carrier includes a well having conducting sides and a conducting bottom that are connected to the shielding trace. The well has a depth greater than the die height, and the light receiving die is mounted in the well.

### BRIEF DESCRIPTION OF THE DRAWINGS

FIG. 1 is a perspective view of a prior art transceiver.

FIG. 2 is a cross-sectional view through line 2-2 shown in FIG. 1.

FIG. 3 is a top view of an embodiment of a transceiver prior to the molding of the encapsulation layer.

FIG. 4 is a side view of the transceiver shown in FIG. 3 prior to the molding of the encapsulation layer.

FIG. 5 is a cross-sectional view of the transceiver shown in FIG. 3 after encapsulation.

FIG. 6 is a cross-sectional view of a portion of a transceiver according to one embodiment of the present invention.

FIG. 7 is a cross-sectional view of a portion of a transceiver according to another embodiment of the present invention.

FIG. 8 is a top view of a transceiver according to another embodiment of the present invention.

### DETAILED DESCRIPTION OF THE PREFERRED EMBODIMENTS OF THE INVENTION

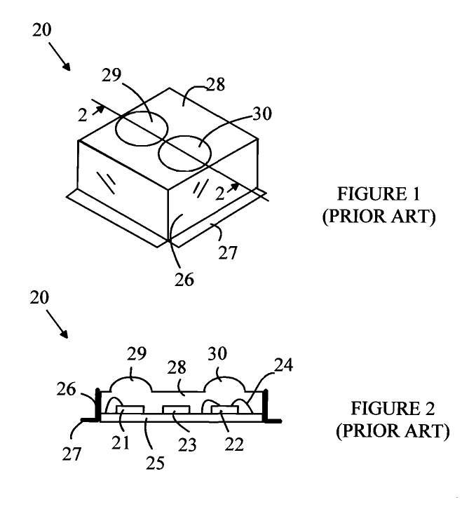

The manner in which the present invention provides its advantages can be more easily understood with reference to FIGS. 1 and 2, which illustrate a prior art transceiver module that utilizes an exterior EMI shield to reduce EMI. FIG. 1 is a perspective view of transceiver 20, and FIG. 2 is a cross-sectional view of transceiver 20 through line 2-2 shown in FIG. 1. Transceiver 20 includes an LED 21 and a photodiode 22 that are bonded to a carrier 25 that includes a number of electrical traces that are utilized to connect the circuit components to the carrier and the carrier to an external printed circuit board or the like. To simplify the drawings, these traces have been omitted. The connections to the top surfaces of the dies containing the LED and the photodiode are made via wire bonds that connect the pads on the top surface of the dies to pads on the top surface of carrier 25. A typical wire bond is shown at 24. The LED and photodiode are typically controlled by a controller 23 that is also mounted on carrier 25 and performs the interface functions needed to connect the transceiver to signal sources and devices that are external to transceiver 20.

After the dies have been mounted on carrier 25 and connected to the various traces either by wire bonds or connection pads on the bottom surfaces of the dies, the dies are encapsulated in a clear layer 28 of epoxy or silicone that can include optical elements such as lenses 29 and 30. Lens 29 images the light from LED 21 on the relevant target, and lens 30 collects light that is to be measured by photodiode 22.

After the encapsulation process is completed an EMI shield 26 is mounted relative to carrier 25. EMI shield 26 is typically constructed from a metal sheet, and can be bonded to the encapsulation layer before transceiver 20 is attached to a printed circuit board, or EMI 26 can be attached to the printed circuit board after carrier 25 is attached to the printed circuit board. Tabs such as those shown at 27 are used to connect EMI 26 to a ground connection on the printed circuit board by solder or some other form of electrically conducting adhesive.

It should be noted that EMI 26 provides only limited protection for EMI that arrives from the same direction that the light entering lens 30 arrives. In principle, EMI 26 could be extended over the top surface of encapsulation layer 28 with cut-outs for lenses 29 and 30 to improve the level of protection. However, this also would also substantially increase the cost of EMI 26, and the protection would still be limited due to the fact that the cutouts would need to be at least as large as the lens.

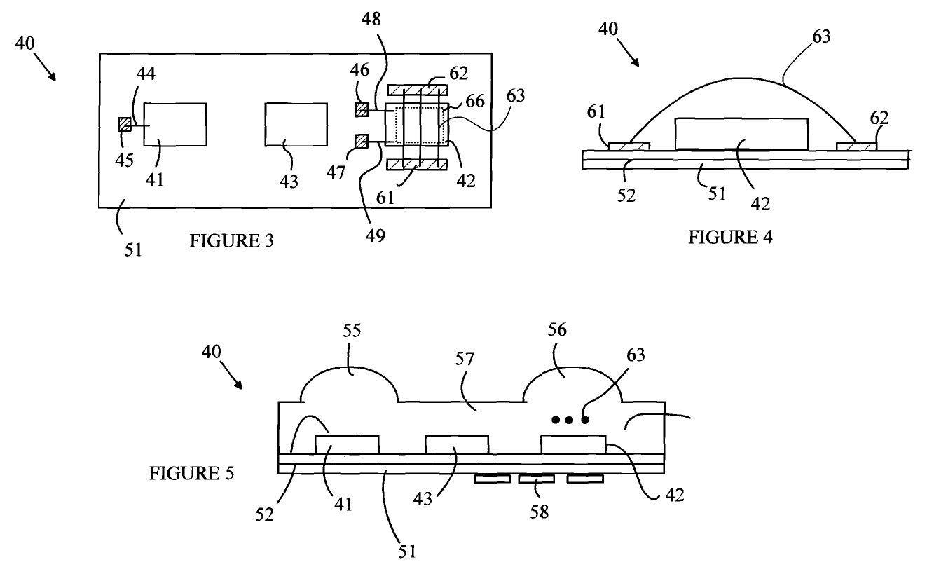

Refer now to FIGS. 3-5, which illustrate a transceiver according to one embodiment of the present invention. FIG. 3 is a top view of transceiver 40 prior to the molding of the encapsulation layer. FIG. 4 is a side view of transceiver 40 prior to the encapsulation layer molding, and FIG. 5 is a cross-sectional view of transceiver 40 after encapsulation.

Transceiver 40 utilizes an EMI shield that is a conductive “layer” that blocks EMI while allowing light to reach the photodiode. The EMI shield can be viewed as a conducting screen constructed from wires that form openings through which the light that is to be received by the photodiode is transmitted. If the screen is grounded, the sheet is seen as a continuous conductive layer by EMI having wavelengths that are large compared to the size of the openings in the screen. The openings in the screen are large compared to the wavelengths of the infrared light that is to be measured, and hence, with the exception of the fraction of the light that is blocked by the wires, the screen is transparent to the infrared light. The wire diameters used to construct the screen are typically 25 μm and block less than 5% of the light when used with a typical photodiode die.

Refer now to FIGS. 3 and 4. Transceiver 40 includes a light source comprising an LED 41 and a receiver comprising photodiode 42. The light source and receiver are interfaced to a controller 43. The light source, receiver, and controller are mounted on a carrier 51 that includes a number of electrical traces that are utilized to connect these components to one another and to the device to which the transceiver is finally connected by a number of connection pads 58 on an outside surface of transceiver 40. These traces can be implemented on one or more conductive layers within carrier 51 in a manner analogous to that utilized in a conventional printed circuit board. In one embodiment, carrier 51 is a small printed circuit board. To simplify the drawing, the electrical traces have been omitted from the drawing.

The LED and photodiode are assumed to have contacts on the top surface of the dies that must be connected to traces in carrier 51. These connections are normally made via wire bonds that connect the contacts to corresponding bond pads on carrier 51. For example, LED 41 is driven by applying a signal between one contact on the bottom surface of LED 41 and one contact on the top surface of the LED that is connected to bond pad 45 by wire bond 44. The contact on the bottom surface of LED 41 is bonded to a corresponding pad on the top surface of carrier 51; this connection is hidden in the drawing. Similarly, photodiode 42 has two contacts on the top surface of the die that are bonded to pads 46 and 47 by wire bonds 48 and 49, respectively. In general, photodiode 42 has an aperture 66 on the top surface of the die through which light that is to be measured enters the photodiode.

An EMI shield is constructed from a number of wires that are connected between two bond pads 61 and 62 on the top surface of carrier 51 by conventional wire bonds. A typical wire used in the EMI shield is shown at 63. Bond pads 61 and 62 are connected to a ground plane 52 in carrier 51. Hence, the EMI shield surrounds photodiode 42 while allowing essentially all of the light intended for photodiode 42 to reach photodiode 42.

After the various wires have been put in place, the dies, wire, and wire bonds are encapsulated in a clear layer 57 of epoxy or silicone. Layer 57 could also include lenses such as lenses 55 and 56 that perform functions analogous to those discussed above with reference to FIGS. 1 and 2. The wire used to construct the EMI shield are likewise encapsulated in layer 57, and hence, do not increase the size of transceiver 40. The wires can be made from the same material utilized in making the connections between the contacts on the dies and the bonding pads on the carrier.

It should be noted that the cost of providing the additional wire bonds is small compared to the cost of providing an external shield since the wire bonding process is a normal part of the fabrication on the transceiver. In addition, the shield is constructed by the transceiver manufacturer, and hence, the maker of the final product is relieved of the task of providing the EMI shield and a product design that can accommodate the additional size and connections required by conventional EMI shields.

The above-described embodiments of the present invention utilize an EMI shield constructed from wires that run parallel to one another in one direction. However, other arrangements could be utilized. For, example, additional wires could be provided running at right angles to the ones shown in FIG. 3. In addition, the wires could cross each other at angles other than 90 degrees. Any arrangement that provides a two dimensional conducting fabric having sufficiently large holes to allow the required fraction of the light to reach the photodiode could be utilized.

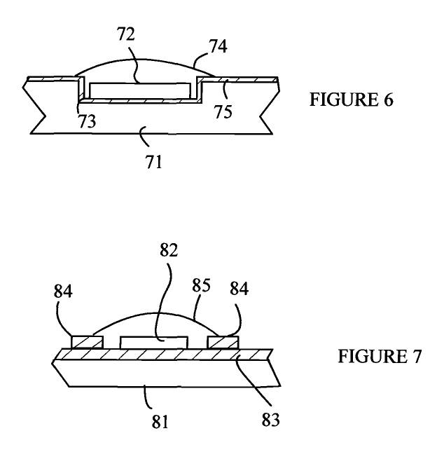

In the above-described embodiments of the present invention, the die having the photodiode is protected by placing shielding wires over the die. Additional protection from EMI can also be provided by mounting the die in a well having a conducting lining that is also held at ground. Refer now to FIG. 6, which is a cross-sectional view of a portion of a transceiver in which the photodiode is located on a die 72 that is mounted in a well 73 formed in carrier 71. The inside surface of well 73 is lined with a layer of metal 75 that is connected to the ground conductors in carrier 71. The shielding wires 74 are connected across well 73 to metal layer 75 by conventional wire bonds.

The well in which the photodiode die is mounted can also be provided by building up a ring around a die that is mounted on a conventional flat carrier. Refer now to FIG. 7, which is a cross-sectional view of a portion of a transceiver in which this approach is utilized. Carrier 81 includes a conducting layer 83 on the top surface thereof. A ring of conducting material 84 extends above layer 83 to form a well in which die 82 is mounted. The shielding wires 85 can be bonded to this ring or directly to metal layer 83 using conventional wire bonding techniques. Ring 84 could be provided by plating additional material onto layer 83 or by bonding a preformed ring to layer 83. It should be noted that die 82 typically has a thickness of about 200 microns, and hence, a suitable ring can be provided by either technique.

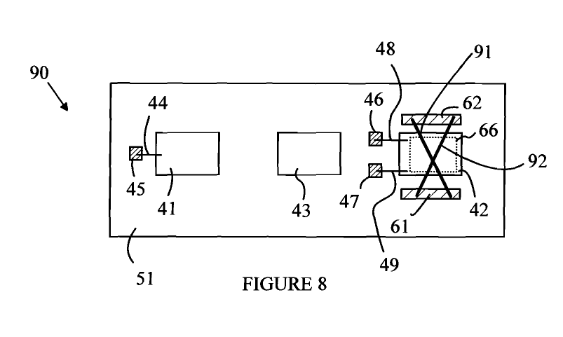

As noted above, the shielding wires can be arranged in any of a number of patterns. It has been found experimentally that a pattern that utilizes crossed wires is particularly effective. Refer now to FIG. 8, which is a top view of another embodiment of a transceiver according to the present invention. Transceiver 90 is similar to transceiver 40 discussed above, with the exception of the shielding wires shown at 63 in transceiver 40. In transceiver 90, the shielding wires are arranged as a pair of crossed wires shown at 91 and 92. It should be noted that additional pairs of cross-wires could also be added to provided additional EMI shielding.

In the above-described embodiments of the present invention, the ground plane that protects the backside of the photodiode is assumed to be in the carrier on which the die is mounted. However, embodiments in which the ground plane is provided by the printed circuit board on which the transceiver is finally mounted could also be constructed. In such embodiments, the shielding wires protect the die from EMI received from the front side of the die and the external ground plane protects the die from EMI received from the reverse direction.

The above-described embodiments utilize a photodetector based on a photodiode. However, the shielding system of the present invention could be utilized with other forms of photodetector such as a phototransistor. In general, the present invention could be utilized with any form of photodetector that has an aperture through which light to be measured enters the photodetector. In such a generalized system, the shielding wires are arranged across the receiving aperture and connected to ground or another power rail that is maintained at a fixed potential.

The shielding system of the present invention has been explained in terms of its use in a transceiver having an optical transmitter and an optical receiver. However, the optical transmitter is not needed to practice the present invention. The shielding system can be applied to any optical receiver whether or not an optical transmitter is also included in the same apparatus. Furthermore, the EMI shield of the present invention could also be applied to non-optical integrated circuits that must be protected from EMI.

Various modifications to the present invention will become apparent to those skilled in the art from the foregoing description and accompanying drawings. Accordingly, the present invention is to be limited solely by the scope of the following claims.

What is claimed is:

1. An apparatus comprising:
a die having a top surface through which EMI is received;
a carrier having a first surface on which said die is mounted by attaching said die to said first surface using a surface of said die other than said top surface, said carrier further comprising a plurality of electrical traces, said die being connected to two of said traces; and
a plurality of shielding wires crossing said top surface of said die and being connected to a shielding trace included in said carrier that is held at a constant potential, said shielding wires reducing said EMI received by said die.

2. The apparatus of claim 1 wherein said die comprise a light receiving die having a light detector thereon that receives light through an aperture on a top surface of said light receiving die, and wherein said aperture underlies said shielding wires.

3. The apparatus of claim 2 further comprising a layer of clear material covering said light receiving die and said shielding wires, said light receiving die being encapsulated by said layer of clear material and said carrier.

4. The apparatus of claim 3 further comprising a light transmitting die bonded to said carrier and covered by said layer of clear material.

5. The apparatus of claim 2 wherein said light receiving die is characterized by a height and wherein said first surface of said carrier comprises a well having conducting sides and a conducting bottom, said conducting sides and bottom being connected to said shielding trace and wherein said light receiving die is mounted in said well, said well having a depth greater than said light receiving die height.

6. The apparatus of claim 2 wherein said shielding wires cover less than 5% percent of said aperture.

7. The apparatus of claim 2 wherein said carrier comprises a plurality of die attachment pads and wherein said shielding wires are bonded to at least one of said die attachment pads by wire bonds.

8. The apparatus of claim 2 wherein said carrier further comprises a conducting layer underlying said light receiving die, said conducting layer being connected to said shielding trace.

9. The apparatus of claim 8 wherein said light receiving die is characterized by a height and wherein said conducting layer comprises a well in which said light receiving die is mounted, said well having a depth greater than said height.

10. The apparatus of claim 3 further comprising a controller for transmitting light signals by said light transmitting die and receiving light signals through said light detector.
